(19) United States
(12) Patent Application Publication
(10) Pub. No.: US 2010/0288352 A1
(43) Pub. Date: Nov. 18, 2010

(54) INTEGRATED SOLAR CELL NANOARRAY LAYERS AND LIGHT CONCENTRATING DEVICE

(75) Inventors: Jin Ji, Boston, MA (US); Lawrence Kaufman, Waltham, MA (US)

Correspondence Address: Milstein Zhang & Wu LLC, 49 Lexington Street, Suite 6, Newton, MA, 02465-1062, US

(73) Assignee: Lightwave Power, Inc., Cambridge, MA (US)

(21) Appl. No.: 12/777,559

(22) Filed: May 11, 2010

Related U.S. Application Data
(60) Provisional application No. 61/177,449, filed on May 12, 2009.
(60) Provisional application No. 61/177,462, filed on May 12, 2009.

(51) Int. Cl. H01L 31/0232

(52) U.S. Cl. 136/256; 257/E31.127

(57) ABSTRACT

An integrated energy conversion device includes a nanoarray layer having a plurality of nanofeatures disposed in a pattern. The nanoarray layer is configured to modify a selected one of a direction and a wavelength of photons of light incident on a surface of the nanoarray layer. The nanoarray layer has a surface. A first material is disposed adjacent to and optically coupled to one region of the surface of the nanoarray layer. A second material is disposed adjacent to and optically coupled to a second region of the surface of the nanoarray layer. At least a selected one of the first material and the second material includes a photovoltaic layer which is configured to provide an integrated solar cell electrical output voltage and an integrated solar cell electrical output current between an integrated solar cell positive output terminal and an integrated solar cell negative output terminal.

### CROSS-REFERENCE TO RELATED APPLICATIONS

This application claims priority to and the benefit of co-pending U.S. provisional patent application Ser. No. 61/177,449, PATTERNED PLANAR DEVICES AS INTERMEDIATE LIGHT DISTRIBUTING AND GUIDING LAYERS IN SOLAR CELLS, filed May 12, 2009, and co-pending U.S. provisional patent application Ser. No. 61/177,462, PLASMONIC AND PHOTONIC STRUCTURES FOR GUIDING AND TRAPPING LIGHT, filed May 12, 2009 which applications are incorporated herein by reference in their entirety.

### FIELD OF THE INVENTION

The invention relates to light management layers in general and particularly to light management device layers that employ nanoarrays.

### BACKGROUND OF THE INVENTION

Integrated solar cells include at least one solar cell or absorbing layer which absorbs photons of light for conversion to electricity. One problem with integrated solar cells is that conventional solar cell layers are relatively thick. The present use of relatively thick solar cell layers increases the amount of raw materials needed for production, as well as the cost of the manufactured integrated solar cell product.

Another problem with conventional integrated solar cells is that conventional antireflective layers cause a loss of photons that could otherwise be converted to electricity. One mechanism of such loss is a cosine dependent loss related to the path length through the antireflective layer. This cosine loss is more significant for off-normal angles of incident light (larger zenith angles).

Also, conventional integrated solar cells need solar cell layers with relatively large surface areas to produce a desired amount of electrical energy. As with relatively thick solar cell layers described hereinabove, relatively large surface areas also translate directly into a need for higher quantities of raw materials and a higher cost of manufactured integrated solar cells.

What is needed is a device layer that more efficiently manages light within a solar cell to allow for use of thinner solar cell layers. What is also needed is an antireflective layer that does not have a path length loss related to the incident light angle. Also, what is also needed is a light concentrating device that allows for use of solar cell layers having smaller surface areas.

### SUMMARY OF THE INVENTION

In one aspect, the invention relates to an integrated energy conversion device that includes a nanoarray layer having a plurality of nanofeatures disposed in a pattern. The nanoarray layer is configured to modify a selected one of a direction and a wavelength of photons of light incident on a surface of the nanoarray layer. The nanoarray layer has a surface. A first material is disposed adjacent to and optically coupled to one region of the surface of the nanoarray layer. A second material is disposed adjacent to and optically coupled to a second region of the surface of the nanoarray layer. At least a selected one of the first material and the second material includes a photovoltaic layer which is configured to provide an integrated solar cell electrical output voltage and an integrated solar cell electrical output current between an integrated solar cell positive output terminal and an integrated solar cell negative output terminal.

In one embodiment, the nanoarray layer is configured as an antireflective layer.

In another embodiment, a selected one of the first material and the second material includes a thin film.

In yet another embodiment, a selected one of the first material and the second material includes glass.

In yet another embodiment, the nanoarray layer is configured such that the integrated energy conversion device responds to an incident light having a zenith angle within a range from zero degrees to substantially ninety degrees relative to the surface of the nanoarray layer.

In yet another embodiment, the nanoarray layer is configured as a light management layer.

In yet another embodiment, the light management layer is configured to reflect a light having a first wavelength and to transmit a light having a second wavelength.

In yet another embodiment, the light management layer is configured to reflect the light having a first wavelength to a first photovoltaic layer and to transmit the light having a second wavelength to a second photovoltaic layer.

In yet another embodiment, at least one of the first photovoltaic layer and the second photovoltaic layer is selected from the group of photovoltaic layers consisting of amorphous silicon, crystalline silicon, microcrystalline silicon, nanocrystalline silicon, polycrystalline silicon, Copper indium gallium selenide (CIGS), and cadmium telluride (CdTe).

In yet another embodiment, the nanoarray layer includes a plurality of nanofeatures having a physical feature selected from the group of physical features consisting of depressions, protrusions, apertures, and voids.

In yet another embodiment, the nanoarray layer includes a plurality of nanofeatures including patches of a metal.

In yet another embodiment, the nanoarray layer includes a patterned metal film.

In yet another embodiment, the nanoarray layer further includes a Lambertian surface disposed on a surface of the nanoarray.

In yet another embodiment, the nanoarray layer includes a metal selected from the group consisting of silver, gold, copper, aluminum, nickel, titanium, chromium, silver alloy, gold alloy, copper alloy, aluminum alloy, nickel alloy, titanium alloy, chromium alloy, and a combination thereof.

In yet another embodiment, the nanoarray layer includes a transparent conductive oxide material.

In yet another embodiment, the transparent conductive oxide material is an oxide selected from the group consisting of indium-tin-oxide (ITO), zinc oxide (ZnO), aluminum doped zinc oxide (AZO), and tin oxide (SnO2).

In yet another embodiment, a selected one of the first material and the second material includes a waveguide layer having a waveguide layer first surface and a waveguide layer end surface. The second region of the nanoarray layer surface is disposed adjacent to and optically coupled to the waveguide layer first surface. A selected other one of the first material and the second material includes a photovoltaic section disposed adjacent to and optically coupled to the waveguide layer end surface.

In yet another embodiment, the integrated energy conversion device further includes an antireflective layer disposed on the first region of the nanoarray layer surface.

In yet another embodiment, the antireflective layer includes a selected one of an antireflective coating and a nanoarray layer.

In yet another embodiment, the integrated energy conversion device further includes a selected one of a mirror layer disposed adjacent to and optically coupled to a waveguide layer second surface and an additional nanoarray layer disposed adjacent to and optically coupled to a waveguide layer second surface.

In yet another embodiment, the integrated energy conversion device further includes at least one additional tandem nanoarray waveguide concentrator device disposed substantially adjacent to and optically coupled to the nanoarray waveguide concentrator device.

In yet another embodiment, the nanoarray waveguide concentrator device and the additional nanoarray waveguide concentrator device are configured to operate in different wavelength bands.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 shows a cross section diagram of an array of nanoparticles formed at an interface between two materials.

FIG. 2 shows a cross section diagram of a plurality of nano-apertures.

FIG. 3 shows a cross section drawing of a nanoarray device having an additional diffraction or resonant plasmonic structure.

FIG. 4 shows a cross section drawing of a device layer having an array of voids.

FIG. 5 shows a cross section diagram of an exemplary embodiment of an integrated solar cell having a wavelength down conversion layer and a light management layer.

FIG. 6 shows a cross section diagram of an exemplary embodiment of an integrated solar cell having a wavelength up conversion layer and a light management layer.

FIG. 7 shows one exemplary plan view of a planar nanopatterned layer suitable for use in a nanoarray layer light management layer.

FIG. 8 shows one exemplary plan view of a nanoarray having a composite pattern of nanofeatures.

FIG. 9 shows a cross section view of a nanoarray layer having two different coupling element symmetries.

FIG. 10A shows a cross section diagram of a portion of a solar cell having an antireflective layer illuminated by light having a first angle of incidence.

FIG. 10B shows a cross section diagram of the solar cell of FIG. 10A illuminated by light having a second relatively shallow angle of incidence.

FIG. 11 shows a cross section diagram of one exemplary embodiment of a solar cell having an antireflective nanoarray layer which provides the function of a conventional antireflective layer.

FIG. 12 shows a cross section diagram of one exemplary embodiment of a nanoarray waveguide concentrator device.

FIG. 13 shows cross section diagram of one exemplary embodiment of a nanoarray waveguide concentrator device having two nanoarray layers.

FIG. 14 shows a cross section diagram of an exemplary embodiment of a nanoarray waveguide concentrator device that also has a conventional surface mirror.

FIG. 15 shows a cross section diagram of an exemplary embodiment of tandem nanoarray waveguide concentrator device.

### DETAILED DESCRIPTION

### Definitions

Integrated solar cell: We refer herein to a complete solar cell assembly of layers as an “integrated solar cell”. The term integrated solar cell, includes integrated structures made using both conventional semiconductor manufacturing methods, e.g. photolithography and vapor deposition, as well as layers manufactured in part or entirely by more recent fabrication methods, such as for example, nanofabrication methods.

Solar cell layer: The absorber of an integrated solar cell is referred to interchangeably herein as a “solar cell layer”. It is understood that one or more solar cell layers are electrically coupled within an integrated solar cell to provide an integrated solar cell electrical output voltage across an integrated solar cell positive terminal and an integrated solar cell negative terminal. In some embodiments a metal film present for optical reasons can also, but not necessarily, provide as an electrical connection to a solar cell layer.

Nanoarray layer: A nanoarray layer is a layer is a layer having a plurality of nanofeatures. Although the nanoarray layer are generally depicted in the individual drawings of exemplary embodiments as having nano-apertures, or nanoparticles, a nanoarray can include nanoparticles, nano-apertures, other nano features, patches of metal, or any combination thereof. A nanoarray layer generally has a regular parallel or piped geometric form. We define the “surface” of a nanoarray layer to be the surface that bounds the volume of the nanoarray layer. For example in a Cartesian three dimensional (3D) coordinate system, a rectangular nanoarray layer surface includes the two length times width areas, the two width times height areas as well as the two height times length areas (all of the surface areas of the rectangular volume). It is also contemplated that in some embodiments a nanoarray layer can have other geometric forms. Any bounding surface of a volume that can be defined in any suitable 3D coordinate system can be considered to be a nanoarray layer surface. For example, the surface of a cylindrically shaped nanoarray layer can be defined in a 3D cylindrical coordinate system and includes the area of the cylindrical curved surface plus the end surfaces, and the surface of spherically shaped nanoarray layer can be defined in a spherical 3D coordinates system and includes the bounding spherical surface.

Modification of light: Modification of light as used herein includes a change in direction of propagation and/or a change in wavelength of the light.

### INTRODUCTION

We describe hereinbelow several embodiments of planar devices that can modify light. The planar devices include nanolayers having patterns composed of nanofeatures. We believe such devices can be used, for example, as intermediate layers in integrated solar cells to guide and distribute light of selected wavelengths to different layers adjacent to the device. Such nanoarray layer based devices can be used to distribute the incident broadband spectrum electromagnetic waves into two portions. For example, in some embodiments, one portion of an incident light having electromagnetic waves of particular wavelengths is reflected, while another portion having electromagnetic waves of different wavelengths is transmitted through the planar device and enter into a different layer, such as an adjacent layer. It is believed that in additional to selectively splitting the electromagnetic waves into two groups, such devices can also control the propagation angle of the waves to direct photons of light to different layers of an integrated solar cell at angles to maximize photon-to-electron conversion. In some light concentrating embodiments, it is believed that such nanoarray based structures can direct light into optical waveguides where classical methods cannot.

### PRIOR ART

Thin films that can control the direction of propagation of light of certain wavelengths have been used by the solar industry to redirect and trap light that otherwise would escape the solar cell before absorption. Conventional photonic crystals have also been used for this purpose. Photonic crystals are composed of regions (typically dielectric materials) with a periodic modulation of the refractive index that only allows the propagation of light in certain regions. Such light guiding can be viewed as an interference phenomenon related to strong multiple scattering of light in alternating regions of high and low refractive index. A similar way to direct the propagation of light is through diffraction gratings that apply grooves or lines on a planar surface to scatter light to generate unique interfering patterns which determine a direction of light propagation.

### Nanolayers Having Patterns Composed of Nanofeatures

By contrast, a nanopatterned planar device can split the incident electromagnetic waves into multiple portions of groups of light, and direct different groups into different directions for propagation is described hereinbelow. U.S. provisional patent application Ser. No. 61/168,292, PLANAR PLASMONIC DEVICE FOR LIGHT REFLECTION, DIFFUSION AND GUIDING, filed Apr. 10, 2009, described metallic 1-dimension (1-D) or 2-dimension (2-D) plasmonic nanostructures to diffract and guide light in solar cells. The 61/168,292 is incorporated herein by reference in its entirety for all purposes. In this description we use such metallic 1-dimension (1-D) or 2-dimension (2-D) plasmonic nanostructures as well as other types of nanoarrays as light management layers in integrated solar cells.

In some embodiments, nanoarray based planar devices can be placed in a solar cell as an intermediate light guiding layer to guide selected groups of light to selected layers of photovoltaic (PV) materials or other materials. For example, when placed in between two PV layers in a multi-junction solar cell, the choice of the wavelengths to be reflected or transmitted depends on the bandgaps of the different PV materials adjacent to the planar device. Such planar devices can be configured to direct selected electromagnetic waves to a particular PV layer where the selected electromagnetic waves can make a more efficient contribution to electron generation. Depending on the solar cell configuration and the angle of the light entering the various PV layers, an integrated solar cell has an optimum range where the light can have maximum optical absorption path in a PV layer. The nanostructures of a nanoarray on the planar device can be configured to bend and direct light to a predetermined angle so that the light can enter a PV layer at or near an optimum range of incident angle. As a result, the overall absorption of photons in an integrated solar cell can be improved, such as by effectively lengthening the light path in solar cells, as well as causing a more efficient photo-to-electron conversion due to selective wavelength guiding. Also, the thickness of the PV layers can be minimized by the presence of such planar devices that include nanolayers having patterns composed of nanofeatures. With reduced thickness, less raw materials are needed, and the overall cost of an integrated solar cell using a nanoarray based planar device as described hereinbelow is also reduced over conventional integrated solar cell structures of the prior art.

### Nanoarrays as Layers of Integrated Solar Cells

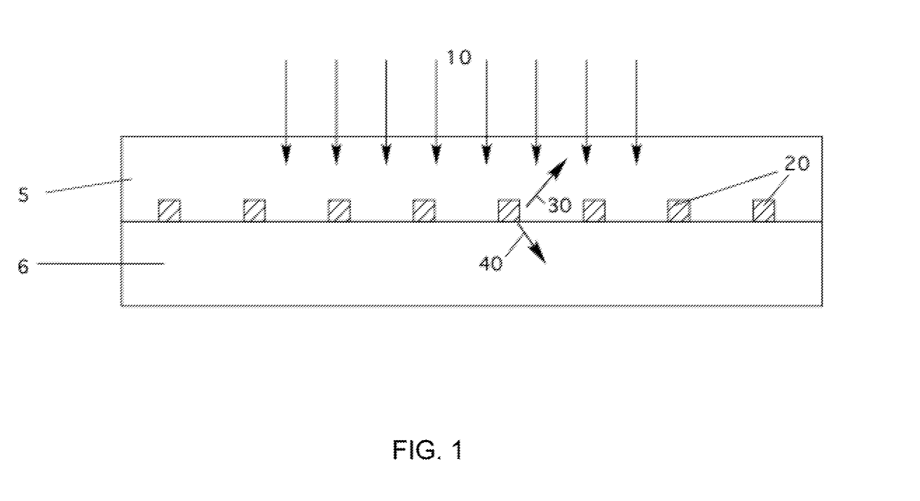

FIG. 1 shows a cross section diagram of an array 20 of nanoparticles formed at an interface between a material 5 and a material 6. Photons represented by light rays 10 are incident on the material 5. Some of the photons propagate to the nanoparticles 20. Owing to surface plasmon effects, as further described hereinbelow, some of the photons of light rays 10 are absorbed and re-emitted as photons represented by light rays 30 back into the material 5 and some of the rays are absorbed and re-emitted as photons represented by light rays 40 into material 6. The distribution of photons represented by light rays 10 into photons represented by light rays 30 and photons represented by light rays 40 depends on the wavelengths of the rays, and the geometry of the nanoparticles.

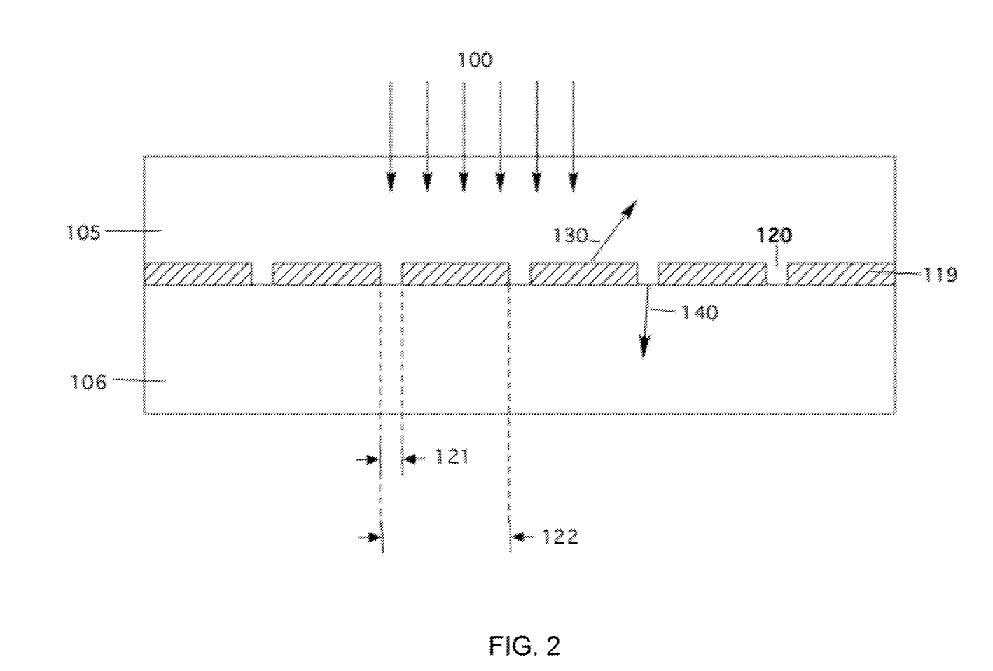

FIG. 2 shows a cross section diagram of nano-apertures. Nano-apertures 120 are formed in a nanoarray layer 119 that can be made of a metal or other dielectric placed at the interface between a material layer 105 disposed adjacent to a material layer 106. Photons of light represented by light rays 100 are incident on material 105. Photons of light represented by rays 130 are reflected by the nanoarray layer 119, and photons of light represented by light rays 140 are transmitted into material layer 106. The wavelengths of the light rays 130 that are reflected and transmitted depend on the dielectric constants as well as the aperture size 121 and the spacing 122.

A planar device of the type shown in FIG. 2 can be used in a multi-junction solar cell to select and direct different wavelength ranges of electromagnetic waves to enter different photovoltaic layers for maximum photon-to-electron generation. For example, in an amorphous-nanocrystalline silicon tandem solar cell, it is typically preferable that a material layer 105 (e.g. comprising amorphous silicon) be thin to minimize the impact of light-induced degradation and to maximize photo-generated carrier collection. However, the use of thin layers limits absorption and therefore the current generated in material layer 105 is limited. To overcome this limited current generation, the nanoarray based planar devices can be implemented in between a top amorphous Si layer (e.g. material layer 105) and a nanocrystalline Si layer (e.g. material layer 106) that reflect a portion of the unabsorbed light back into the amorphous Si layer. Electromagnetic waves of 500-600 nm are most efficiently absorbed in amorphous Si, while electromagnetic waves of 600-800 nm are most efficiently absorbed in nanocrystalline Si layer. In one exemplary embodiment of an integrated solar cell having a device layer according the FIG. 1 or FIG. 2, photons of light of 600-800 nm are directed as photons represented by light rays 140 to the nanocrystalline Si layer, and photons of light of 500-600 nm are reflected back to amorphous Si layer as rays 130 to maximize photon-to-electron conversion efficiency. While the example described hereinabove uses photovoltaic layers of amorphous silicon and nanocrystalline silicon, the same techniques of wavelength selective light direction can be applied to photovoltaic layers made of any suitable type of photovoltaic material, such as, for example, amorphous silicon, crystalline silicon, microcrystalline silicon, nanocrystalline silicon, or polycrystalline silicon, and Copper indium gallium selenide (CIGS), or cadmium telluride (CdTe). Two or more such photovoltaic layers can be made of the same materials or of different materials as in the example. It is understood that an integrated solar cell using such light direction techniques can have a plurality of light management layers and a plurality of photovoltaic layers.

The propagation angle of the light entering various photovoltaic (PV) or solar cell layers has an optimum range related to the maximum optical absorption path in a solar cell layer for a given solar cell configuration. Diffraction and/or plasmonic resonant structures can be added on either or both surfaces of a nanoarray layer to achieve these more optimal ranges of propagation angles. Diffraction-grating based surface plasmon resonance can also be used to generate resonance between surface plasmons to diffract light at various angles.

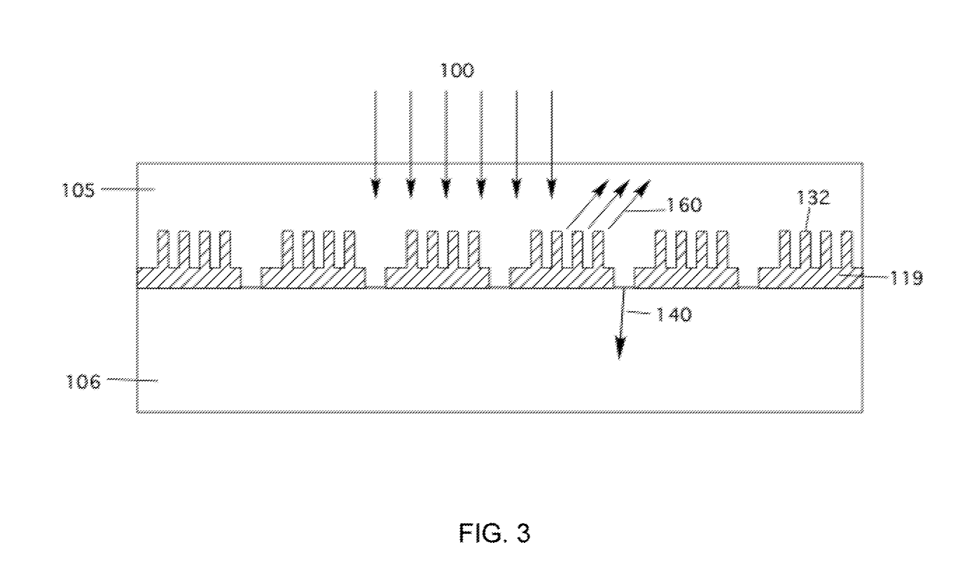

FIG. 3 shows a cross section drawing of a nanoarray device having additional diffraction or plasmonic resonant structures 132 on the surface of the of a nanoarray layer 119 of the planar device layer. Structures 132 influence the propagation direction of the reflected and transmitted photons of light represented by light rays 160.

Plasmonic half-shell nanocups have also been demonstrated to receive selected electromagnetic waves and to direct the propagation of the selected electromagnetic waves. Alternatively, a nanoarray surface can be textured to provide Lambertian scattering. By placing diffraction or plasmonic resonant structures on a nanoarray device layer, such as a planar nanoarray device, the direction of photons of light propagating within various thin solar cell layers can be controlled to obtain maximum light absorption.

The nano-structures (plasmonic structures) discussed hereinabove can also, in some cases, be replaced by a photonic structure or include additional plasmonic structures or photonic structures as well as traditional grating structures. Nanoarray layer 119 can be made from an electrically conductive material that supports plasmon waves, a dielectric material, or any suitable combination thereof. Such materials include, but are not limited metals such as, for example, silver, gold, copper, aluminum, nickel, titanium, chromium, silver alloy, gold alloy, copper alloy, aluminum alloy, nickel alloy, titanium alloy, chromium alloy, and a combination thereof. An electrically conductive material can also be formed from a transparent conductive oxide material such as indium-tin-oxide or zinc oxide materials.

The shape and pattern of these intermediate light guiding nanostructure based planar devices, whether they are apertures or nanoparticles, can include, for example, regular or irregular polygons, circles, ellipses or any other suitable geometric pattern. The thickness of nanoarray layer 119 typically has a dimension ranging from the skin depth of a photon of solar light to several hundreds of nanometers. The pattern of a nanoarray layer, such as nanoarray layer 119, can also include a plurality of shapes such as, rods, rectangles, triangles, linear ridges, circular ridges, spiral ridges, and stars. Each one of the shapes can also have a physical dimension of about a wavelength of light, such as, for example, in a wavelength range of the terrestrial solar spectrum (about 300 nm to 2000 nm). Nanoarray layer 119 can also include a regular array of nanoparticles or nano-apertures in a periodic pattern. Alternatively, nanoarray layer 119 can have a random or non-periodic pattern of nanostructures. For example, a film can have an array of nano-apertures (e.g. as shown in FIG. 2). Alternatively, a nanoarray layer 119 can have a pattern of indentations that do not extend all the way through a film.

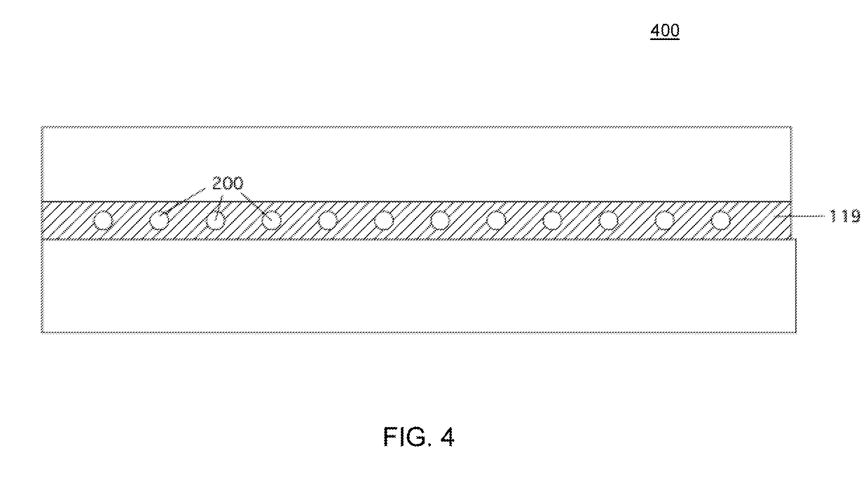

FIG. 4 shows a cross section drawing of a device layer 400 having an array of voids 200 disposed between the surfaces of the nanoarray layer 119. Such physical features can also include any combination of two or more types of protrusions, depressions, apertures, or voids. For example, a nanopattern can be formed from shapes having apertures surrounded by one or more protrusions. Or, a nanopattern can be formed from shapes having voids surrounded by a plurality of depressions.

As described hereinabove, nanoarray based planar devices (e.g. devices having nanopatterned layers and/or combined nanopatterned-Lambertian layers) can be used on or near a surface of an integrated solar cell or within and/or between other device layers (e.g. photovoltaic layers (absorbers) and wavelength conversion device layers) of an integrated solar cell to improve light management. For example, a planar device (e.g. FIG. 1, FIG. 2, and/or FIG. 3) can be incorporated into a multi junction solar device between two adjacent PV layers such as between an amorphous silicon and a nanocrystalline silicon, or between any two adjacent layers of an integrated solar cell.

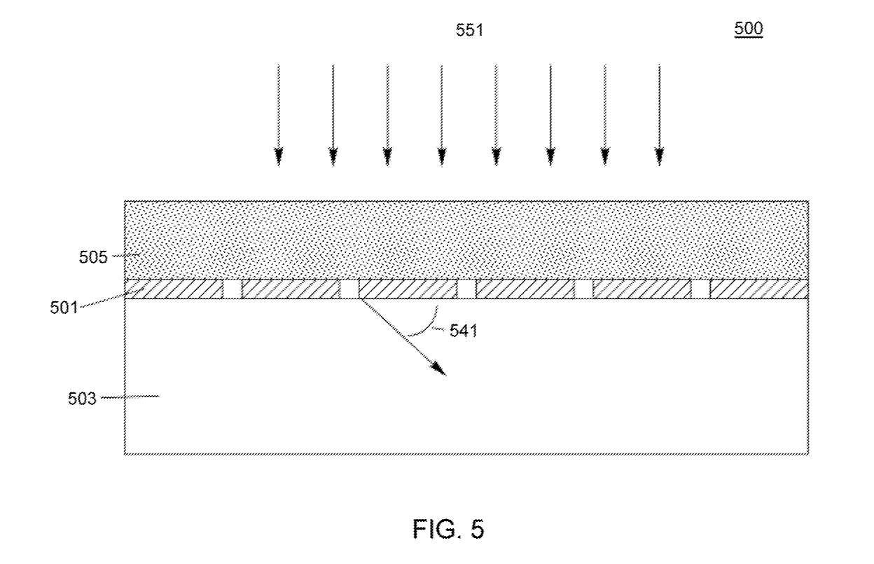

FIG. 5 shows a cross section diagram of one exemplary embodiment of an integrated solar cell 500 having a nanoarray layer 501 configured as a light management layer. Nanoarray layer 501 is disposed between a solar cell layer 503 and a wavelength down conversion layer 505. Incident photons represented by light rays 551 are absorbed and re-emitted by the wavelength down conversion layer 505. In the embodiment of FIG. 5, nanoarray layer 501 controls the propagation angle 541 of light into the solar cell layer 503. With the addition of the intermediate light management layer (nanoarray layer 501) down converted photons emitted by wavelength down conversion layer 505 can thus be more efficiently trapped and converted to electrical energy within the solar cell layer 503.

Wavelength conversion layers, such as wavelength down conversion layer 505, have been described by the Lightwave Power Corporation, for example, in co-pending PCT Application No. PCT/US09/36815, entitled INTEGRATED SOLAR CELL WITH WAVELENGTH CONVERSION LAYERS AND LIGHT GUIDING AND CONCENTRATING LAYERS, filed Mar. 11, 2009, techniques of wavelength conversion layers in solar cells where the wavelength of an incident light can be converted to wavelengths more suitable for efficient absorption by particular photovoltaic (PV) layers of an integrated solar cell structure. The PCT/US09/36815 application is hereby incorporated herein by reference in its entirety for all purposes. Any of the integrated solar cell embodiments described herein, including integrated solar cells having intermediate nanoarray device layers (e.g. planar plasmonic devices) on or near the front, back, or both near the front and the back of an integrated solar cell, can include one or more additional up or down converting layers, such as those described in the PCT/US09/36815 application.

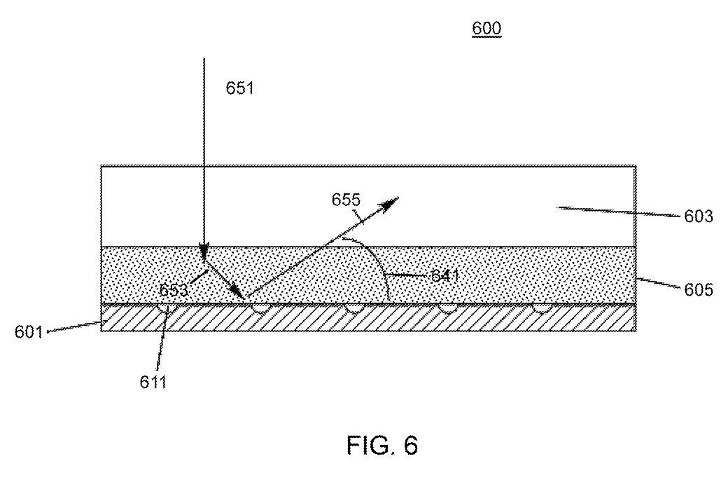

FIG. 6 shows a cross section diagram of another exemplary embodiment of an integrated solar cell 600 having a wavelength up conversion layer 605 and a nanoarray layer 601 configured as a light management layer. A first surface of the wavelength up conversion layer 605 is shown stacked adjacent to nanoarray layer 601 having a plurality of nanofeatures 611. A solar cell layer 603 is stacked adjacent to a second surface of the wavelength conversion layer 605. In operation, photons represented by light rays 651 that pass through the solar cell layer 603 and are wavelength up converted in layer 605 to photons represented by light ray 653 which are absorbed by nanoarray layer 601 and re-emitted at angle 641, as photons represented by light ray 655 back into solar cell layer 603 where the photons of light ray 655 are absorbed.

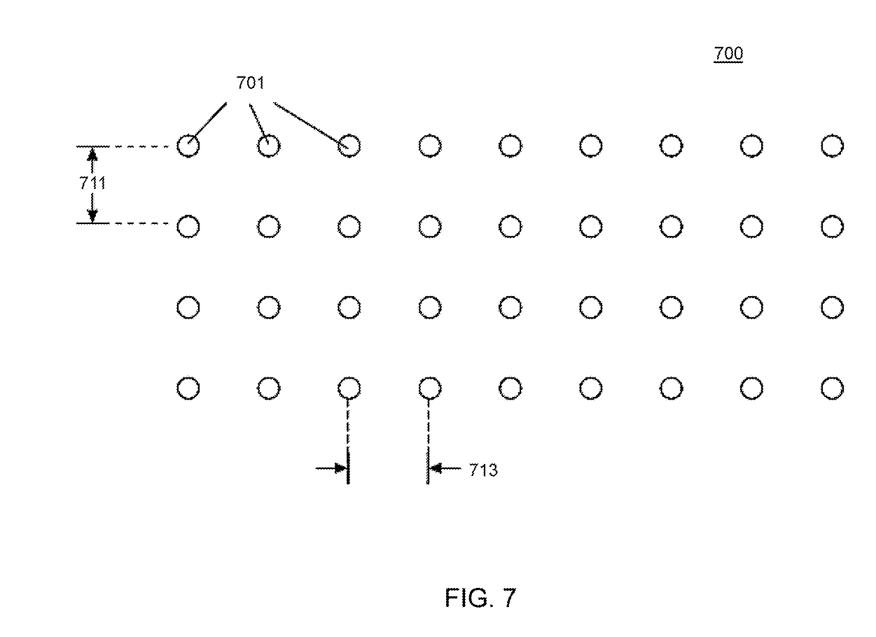

FIG. 7 shows one exemplary plan view 700 of a planar nanopatterned layer suitable for use in a nanoarray layer light management layer. Nanofeatures 701 are shown as in a periodic array or lattice, which has a spacing 711 on one axis and 713 on an orthogonal axis. The two orthogonal spacings may or may not be equal, and the array need not be periodic. Both spacing 711 and spacing 713 are typically in a range of 100 nm to 1000 nm, and are selected based on the desired wavelength selectivity.

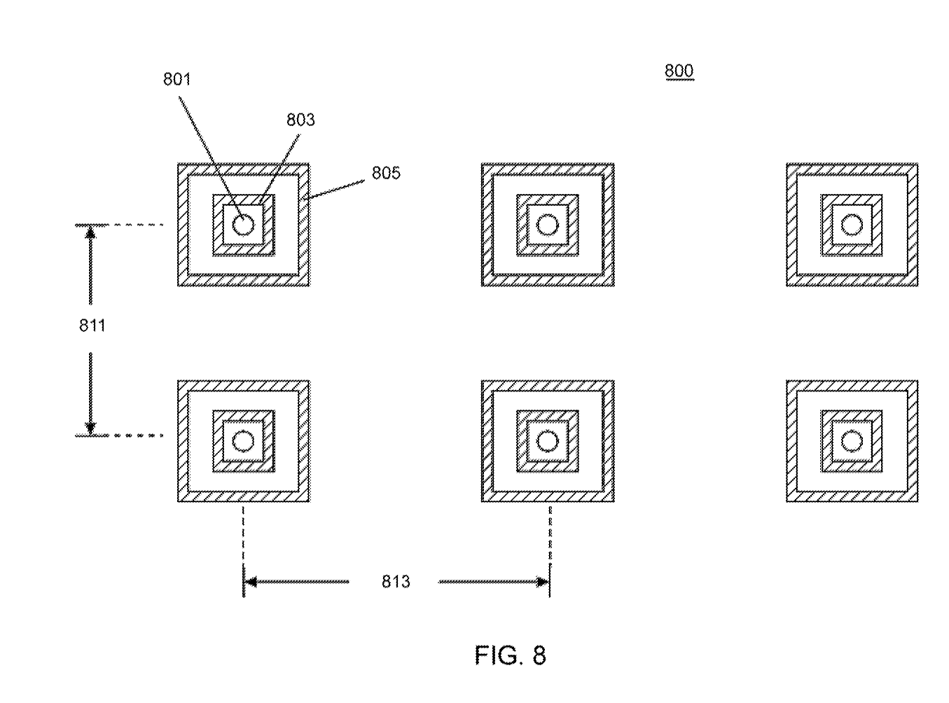

FIG. 8 shows one exemplary plan view of a nanoarray 800 having a composite pattern of nanofeatures. Primary features 801 are decorated with secondary features 803 and 805 to create a coupling pattern which is used to control wavelength selection. Similar composite pattern of nanofeatures are shown in the cross section drawing of FIG. 3. In plan view, the nanofeatures can be of any suitable shape including, for example, square, round or any other suitable polygon or composite shape. As previously described, such nanofeature can be raised in cross section, (e.g. FIG. 3), depressed (e.g. FIG. 6), can penetrate a layer, or can be made using inclusions or voids (e.g. FIG. 4). The side walls of such features can be either straight or tapered. Primary and secondary nano features (different parts of the nanoarray pattern) can be made of different materials, and can include a combination of metals and dielectric materials.

The degree of physical separation of individual nano-features influences the optical properties of the nanoarray. For example, in the embodiment of FIG. 8, if the separation 811 of adjacent elements of the pattern is less than the extension of the electromagnetic field (or separately the electric or magnetic field) of, for example, a light induced plasmon-polariton, then the adjacent elements can be said to be coupled. The coupled interaction can be dependent on the strength of the coupling which in turn depends on the separation distance, the types of materials and the shapes of the individual elements of the nanoarray. At sufficiently close separation distances of the elements of a nanoarray (<1,000 nm), the entire array can be coupled and act as a single whole element.

The in-plane symmetry (the plane of the thin film forming the nanoarray is assumed to be in the plane indicated by nanoarray spacings (e.g. spacings 711 and 713 in FIG. 7 and spacing 811 and 813 in FIG. 8) can influence the interaction of the nanoarray with incident light. For example nanoarray features or elements with a high degree of x-y in-plane symmetry, such as for example circular holes in a circular array of hole elements, should interact with light relatively independent of the angle from the x-axis.

In describing angles of incidence, the zenith is taken by convention to be directly normal or orthogonal (i.e. the z axis) to an x-y plane of the incident surface of an integrated solar cell in the horizontal plane. The zenith angle is the angle defined by a ray representing an incident light from a distant point source (e.g. solar illumination of an integrated solar cell on the Earth). If nanofeatures (e.g. nanofeatures 803 and 805) also have a high degree of in-plane symmetry, the light interactions with the nanoarray should be relatively independent of zenith angle (angle relative to the z axis). As such, nanoarrays as described herein can be configured so that an integrated energy conversion device responds to an incident light on a surface of the integrated energy conversion device where the incident light has a zenith angle within a range from zero degrees to substantially ninety degrees. The angle of incidence can change with time. In one embodiment, the integrated energy conversion device is an integrated solar cell.

Coupling methods of nanoarray elements and symmetry of nanoarray elements and nano-features as described hereinabove can be applied to light emission from a nanoarray. The angular dependence of light emission and wavelength dependence can be influenced by the distance between nanoarray elements and the symmetry of these elements. Light emission from a nanoarray can occur either on the same side of the nanoarray where light absorption takes place or from the opposite side.

Nanofeatures 803 and 805 can also be arranged on the opposite side of the Nanoarray from the incident light. In such configurations, the coupling array can be disposed on an opposite side from the side or surface where light is incident, sometimes referred to a “bottom side”. The coupling array can influence the direction and characteristics of the light re-emitted by the nanoarray. It is possible to have one configuration of the coupling pattern and nanoarray elements pattern on the incident light side (top surface) of the nanoarray to influence the characteristics of light absorbed by the nanoarray, and a different configuration, including configurations with different symmetry, on the bottom opposite surface to influence the direction and characteristics of light emitted by the nanoarray.

It is believed that energy can be transferred from a top surface of a nanoarray to a bottom surface or to other areas of a nanoarray by means of traveling plasmon-polaritons that propagate along a surface of the nanoarray. If the elements of the nanoarray are thin enough (e.g. less than 50 nm), the possibility of coupling of plasmon-polaritons on a top surface to other plasmon-polaritons on a bottom surface is allowed. The mechanism of energy transfer in this case is believed to be analogous to effervescent coupling where light is transferred from one fiber optic cable to another in close contact due to the electromagnetic field from light in one fiber extending through space into the second fiber.

If the nanoarray coupling patterns contain appropriate sized metal structures that promote Plasmon-Polariton excitations by light, these interactions can be wavelength dependent and the light influenced by the nanoarray can be wavelength dependent with different effects at different wavelengths of light. In some embodiments, it is also believed that if the nanoarray is made of or further includes photonic structures, then the angles of light absorption of incident light and light emission can be modified and these modifications can be designed to be wavelength dependent.

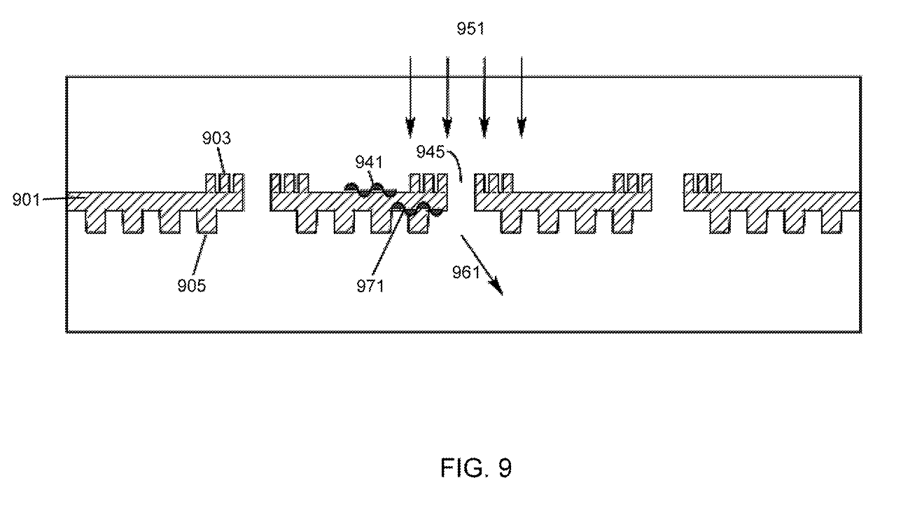

FIG. 9 shows a cross section view of a nanoarray layer device 900 having different coupling element symmetries for the side of the nanoarray exposed to incident light and the opposite side where light is emitted. A first type of coupling element, a front symmetric coupling element 903 is used to modify the nanoarray 901 performance response incident photons represented by light rays 951 incident on a first (front) surface of device 900. Front symmetric coupling element 903 enables a response which is relatively independent of the direction of the incident light within the plane of the device 900. An emitting surface coupling element 905 influence the direction of emitted photons represented by light ray 961.

In operation, photons of incident light represented by light rays 951 interact with the nanoarray 901 by forming Plasmon-polaritons 941 on the first (top) surface of nanoarray 901. Energy can be transmitted by these Plasmon-polaritons to the second (bottom) surface by the Plasmon-polariton excitations that propagate along surfaces including propagation along the surfaces of holes 945 (e.g. holes, voids, or any type of opening or dielectric of any suitable shape) that go through the nanoarray structure, or by coupling of the electromagnetic fields of plasmon-polaritons 941 on the first (top) surface with that of plasmon-polaritons 971 on the second (bottom surface), where the coupling taking place through a sufficiently thin nanoarray structure 901, even one without holes through the whole thickness. Furthermore, in the embodiment of FIG. 9, propagation of energy either through the holes, or through the bulk structure, can be non-linear such that the frequency of plasmon-polaritons and the frequencies of incident and emitted light waves can be modified and changed. Thus, a photon of light incident to a nanoarray layer device, such as device 900, having a first wavelength, can cause an emitted photon of light having a different second wavelength.

### Solar Cell Antireflective Layer

An antireflective layer, typically deposited on the incident light side of a solar cell, is used to reduce reflection and loss of light by increasing trapping efficiency. A conventional antireflective has a relatively constant optical thickness through which photons of incident light travel to reach the underlying layer or layers of the solar cell. Light propagation through a conventional AR layer can be understood by the principles of classical optics.

When considering a solar cell in a plane (e.g. a horizontal plane) on the Earth's surface, and varying zenith angles as the sun rises and sets at the location of the solar cell, there are three basic phenomena that affect the electrical output of the solar cell. The most important is the “cross-section”, a simple geometric term that defines the effective surface area of the solar cell with respect to rays of light from the source. Most desirable is a normal incidence (i.e. zenith angle zero), where the cross-section of the solar cell is substantially its physical active surface area. Least desirable is a full side illumination (i.e. zenith angle ninety degrees), where the effective cross-section is substantially zero. Generally the issue of cross-section is handled either by mounting the cells at an angle from the horizontal plane to best exploit the suns path in a given geographic location or buy use of tracking apparatus to move or point the cells during the day for more optimal azimuth (compass angle in the x-y plane) and zenith angles. Another phenomenon which affects solar cell output is that in the morning and evening hours the solar radiation traverses more of the Earth's atmosphere enroute to the solar cell. The increased atmospheric path length both reduces intensity as well as changes the spectra of the received light since some wavelengths of solar radiation are more attenuated than others. Since this phenomenon represents light that never reaches the solar cell, it cannot simply be “restored” by a corrective method. Lastly, in addition to the effects of cross-section, described first, hereinabove, a solar cell having an antireflective coating suffers an additional loss related to the zenith angle. When the zenith angle is zero, rays of incident light on the surface of a solar cell are normal to the cell (directly overhead a solar cell in the horizontal plane) and the photons of light traverse the smallest distance through the antireflective layer. However, as the zenith angle increases, the photons of light have to traverse longer distances through the material of the antireflective layer.

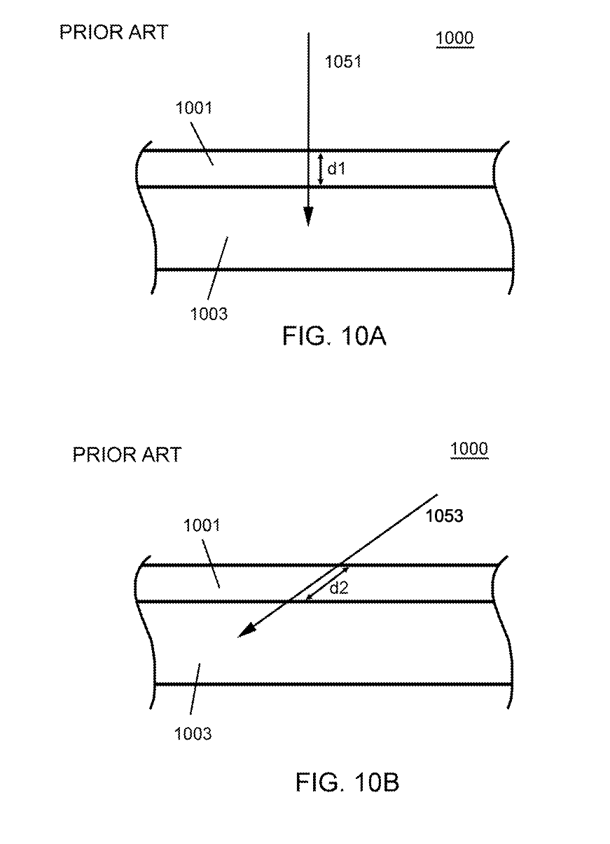

FIG. 10A shows a cross section diagram of a portion of a solar cell 1000 having an antireflective layer 1001 and a first underlying layer 1003. With a zenith angle of zero degrees, photos of light represented by light ray 1051 traverse a distance d1 through antireflective layer 1001 to reach the first underlying layer 1003. However, at a relatively high zenith angle (e.g. sixty degrees) as shown in FIG. 10B, photons of light represented by light ray 1053 traverse a larger distance d2 through antireflective layer 1001 to reach the first underlying layer 1003. This loss can be represented as a cosine dependence.

### Nanoarray Antireflective Function Device

Unlike the losses attributable to the atmosphere, the losses related to the antireflective layer which occur at or near the surface of the solar cell, can be corrected by substitution of different type of device layer that can perform the function of a conventional antireflective layer according to the prior art. We believe that a nanoarray layer based planar device as described herein can be used as a solution to antireflective layer cosine loss. Since a nanoarray layer does not transmit photon lights by simple traversal through a material as described by classical optics, the prior art cosine dependent antireflective layer attenuation can be substantially eliminated. Moreover, since a nanoarray layer modifies light, in addition to performing the function of an antireflective layer, there can be additional functions such as modification of the direction and/or wavelength of the photons.

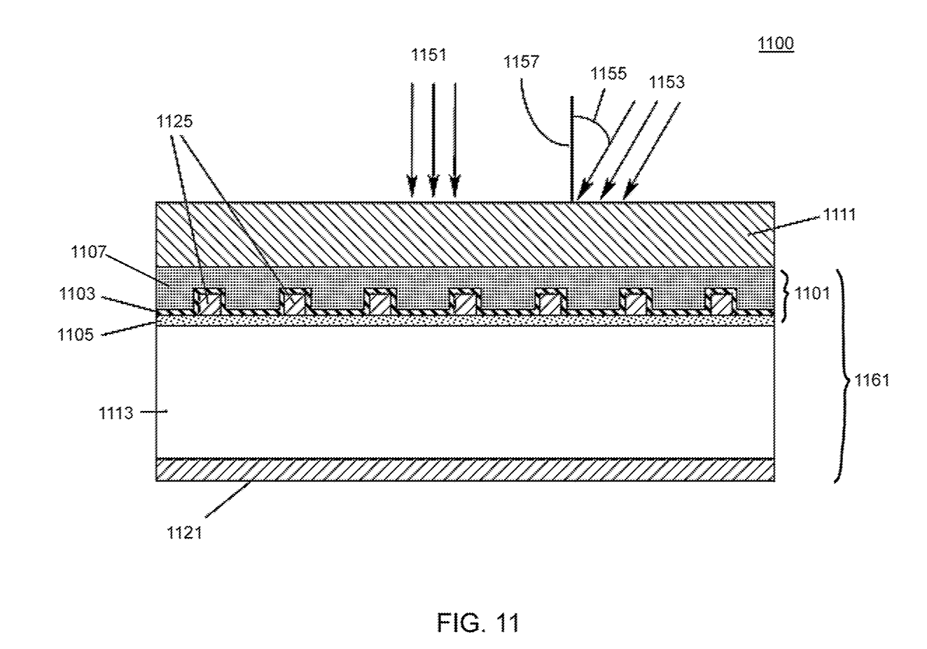

FIG. 11 shows a cross section diagram of one exemplary embodiment of a solar cell 1100 having an antireflective nanoarray layer 1101 which reduces reflection losses by providing the function of a conventional antireflective layer without the cosine dependent attenuation described hereinabove. Integrated solar cell 1100 includes a solar cell layer 1113 (typically an absorbing material), a back surface contact 1121 (which contact can also be a back surface reflector), and other conventional aspects of integrated solar cells (such as p and n doping and front contact metal) integrated with nanoarray layer 1101 having a plurality of nanofeatures 1125. Nanofeatures 1125 can be disposed on solar cell layer 1113 or on an intermediate oxide, nitride or thin film, such as, for example, a thin film 1105. Where an oxide is used, the oxide can be, for example, silicon dioxide, titanium dioxide, tin oxide, indium tin oxide, or zinc oxide. A thin film layer, such as thin film 1105, can also serve as a surface passivation layer, diffusion barrier, anti-reflection layer, or a conductive layer as known in the prior art. Nanofeatures 1125 can be coated with a layer (e.g. layer 1103) for optical and/or electrical purposes. The structure 1161 can also be optionally bonded to a glass layer 1111, such as by use of an adhesive 1107, or a structure 1161 can be deposited directly on such a glass layer.

The anti-reflective properties of the plasmonic nano-array are less sensitive to angle of incidence than conventional quarter wave coatings, because the optical thickness of a quarter wave coating is geometrically (1/cos θ) dependent on the angle of incidence, θ. A nano-array reflectance of a nanoarray layer 1101 however is generally not substantially geometrically dependent on the angle of incidence.

In operation, photons represented by light rays 1151 are incident on structure 1100 and can be partially reflected at each interface. Most of the reflection occurs at the interface that has the largest change in index of refraction. In the embodiment shown in FIG. 11, typically most reflection occurs at the interface with the solar cell layer 1113. Nanoarray layer 1101 acts to reduce this loss. Additionally, as the sun rises and sets, photons represented by light rays 1153 may be incident at a variety of angles (e.g. angle 1155). Nanoarray layer 1101 substantially reduces loss attributable to reflection loss at shallower angles (larger zenith angles), and thus increases the total daily conversion of sunlight to electricity.

### Light Concentrator Device

A light concentrator is a device that can increase the number of photons on a given light receiving surface area by collecting light equivalent a larger surface area than the receiving surface area. For example, a solar concentrator can increase the number of photons incident a photovoltaic surface of an integrated solar cell by collecting light equivalent a larger surface area than the surface area of photovoltaic surface.

One type of solar concentrator is a luminescent solar concentrator (“LSC”). A conventional LSC is usually made from a plastic or polymer light collector sheet incorporating a dye. A photovoltaic solar cell is attached to the side. The process of harvesting solar energy starts when light enters the LSC and the incorporated dye absorbs the light. The dye re-emits the light, usually isotropically, with some of the light emitted by the dye at angles that are trapped inside the LCS by total internal reflection. Some of the light is reflected off the internal surfaces and so propagates to the side of the LSC which is bonded to a photovoltaic cell, some of the light is re-absorbed by the dye and some of the light is absorbed the LSC ultimately turned into heat. The overall concentration ratio is the ratio of the top surface to the side surface of the LCS, multiplied by the fraction of incident light that effectively makes the journey to the side of the LSC.

It would be highly desirable to build a waveguide concentrator, where the concentration ratio is determined by dividing the area of the surface upon which light is incident by the area of the solar cell. For example, a square waveguide concentrator having a surface length and width of x would have a surface area of x². The area of a solar cell mounted at the side would have an area given by the product of the length of a side (x) and the thickness. If the thickness is y, then the solar cell area is x*y. For a square concentrator device, ¼ of the total concentrated light would be incident on each of the solar cells mounted at the side. The concentration ratio is thus x/4y. For a surface waveguide concentrator having a thickness of 1 mm, and surface length and width of 1 m, the concentration ratio is 250. Unfortunately, by Snell's law of classical optics, there is not a solution where light can be coupled directly from an incident surface into total internal reflection modes from the standard incident light angles. The re-emission of light within an LCS device gives a light concentrating effect by re-emission of light within the LCS layer, a far less efficient process than if it were possible to more directly couple light into a waveguide concentrator device.

It is believed that a waveguide concentrator device (a nanoarray waveguide concentrator device) can be made using one or more nanoarray structures. Nanoarray structures, such as resonant structures, can couple light by means other than classical diffraction, such as by plasmonic waves excited on a first surface that re-emit light on a second surface. We describe hereinbelow several embodiments of nanoarray waveguide concentrator devices.

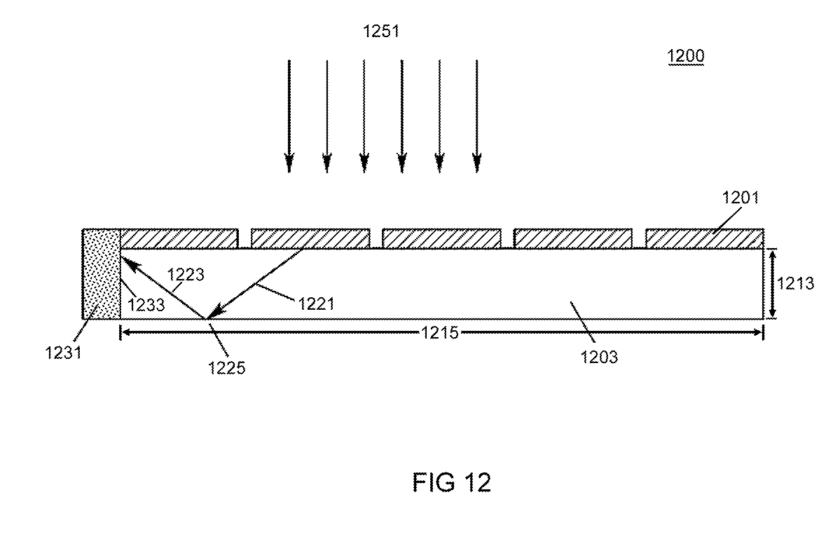

FIG. 12 shows a cross section diagram of one exemplary embodiment of a nanoarray waveguide concentrator device 1200. Nanoarray waveguide concentrator device 1200 includes a waveguide layer 1203 having a layer thickness 1213 and a length 1215 along a long axis of the layer. A photovoltaic section 1231 is disposed adjacent to and optically coupled to one end surface 1233 of waveguide layer 1203. A nanoarray layer 1201 is stacked adjacent to a surface of the waveguide layer 1203.

In operation, photons of light represented by light rays 1251 are incident on a first surface of a nanoarray layer 1201. Nanoarray layer 1201 also can serve as an antireflective surface. A nanoarray layer 1201 (also an anti-reflection layer) has patterns which intercept incident light 1251, so that light is effectively directed into waveguide layer 1203. Photons of light as represented by light ray 1221 are emitted from a second side nanoarray layer 1201 within a range of angles where they are totally internally reflected within the waveguide layer 1203. For example, when light ray 1221 traverses the thickness 1213 of waveguide layer 1203 and reaches the back of waveguide layer 1203 at point 1225, the photons of light are totally internally reflected as represented by light ray 1223 and thereby guided to solar cell 1231 mounted on the end surface of waveguide layer 1203. Since light is transmitted into a nanoarray waveguide concentrator device by a nanoarray layer, a waveguide layer of such devices does not need a dye, as in the LCS devices described hereinabove. However, such devices can optionally also include a dye. As described hereinabove, one measure of the gain of the nanoarray waveguide concentrator device 1200 is the ratio of the surface area of nanoarray layer 1201 parallel to its long axis (dimension 1215) to the surface area of the photovoltaic section 1231 which is disposed adjacent to and optically coupled to an end surface of waveguide layer 1203.

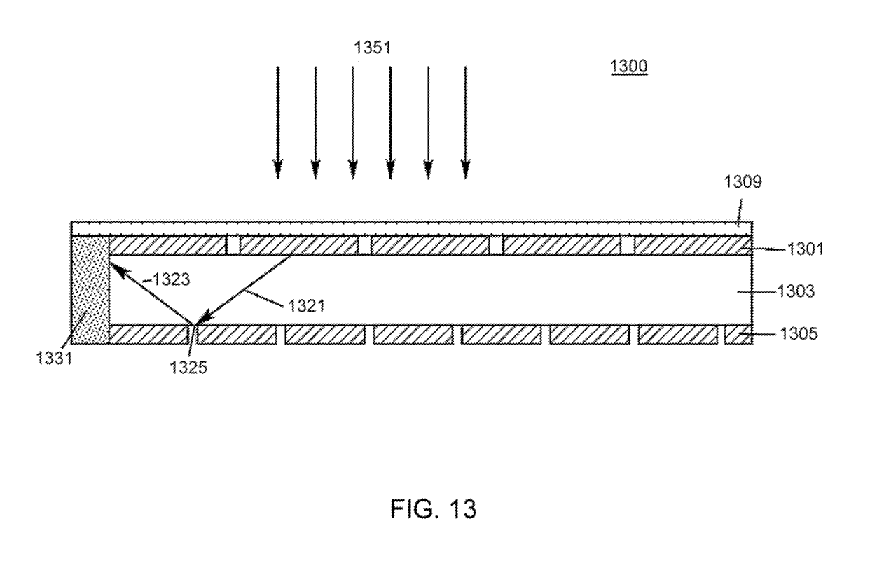

FIG. 13 shows cross section diagram of another exemplary embodiment of a nanoarray waveguide concentrator device 1300 having two nanoarray layers. A nanoarray layer 1301 is stacked adjacent to a first surface of the waveguide layer 1303 closest to a source of incident light represented by light rays 1351. An optional additional antireflective layer 1309, which can be either a conventional antireflective layer or a nanoarray antireflective layer, is shown stacked on a surface of nanoarray layer 1301. A nanoarray layer 1305 is stacked adjacent to the opposite or second surface of the waveguide layer 1303. A photovoltaic section 1331 is disposed adjacent to and optically couple to an end surface of waveguide layer 1303.

In operation, photons of light represented by light rays 1351 are incident on a first surface of the antireflective layer 1309. Photons of the incident light 1351 propagate through the antireflective layer 1309 (by classical optics and/or plasmonic transmission where the antireflective layer is a nanoarray layer) to nanoarray layer 1301. Nanoarray layer 1301 has patterns which intercept light received from the antireflective layer 1309, so that light is effectively directed into waveguide layer 1303. Photons of light as represented by light ray 1321 are emitted from a second side nanoarray layer 1305 within a range of angles where they are totally internally reflected within the waveguide layer 1303. For example, when light ray 1321 traverses the thickness of waveguide layer 1303 and reaches the opposite side of waveguide layer 1303 at point 1325, the photons of light are totally internally reflected as represented by light ray 1323 and thereby guided to solar cell 1331 mounted on the end surface of waveguide layer 1303.

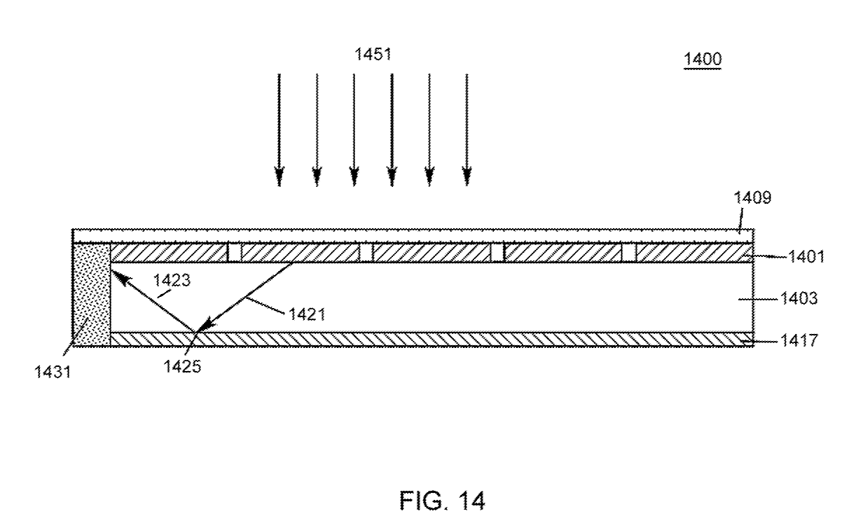

FIG. 14 shows a cross section diagram of another exemplary embodiment of a nanoarray waveguide concentrator device 1400 having a nanoarray layer 1401 is stacked adjacent to a surface of the waveguide layer 1403. A nanoarray layer 1401 is stacked adjacent to a first surface of the waveguide layer 1403 closest to the source of incident light represented by light rays 1451. An optional additional antireflective layer 1409 which can be a either a conventional antireflective layer or a nanoarray antireflective layer is shown stacked on a surface of nanoarray layer 1401. In FIG. 14, however, the nanoarray layer 1305 of FIG. 13 has been replaced by a conventional surface mirror 1417.

The operation of a nanoarray waveguide concentrator device 1400 of FIG. 14 is similar to that of the waveguide concentrator device 1300 of FIG. 13, except that at point 1425, the photons of light are totally internally reflected as represented by light ray 1423 by the conventional mirrored layer 1417.

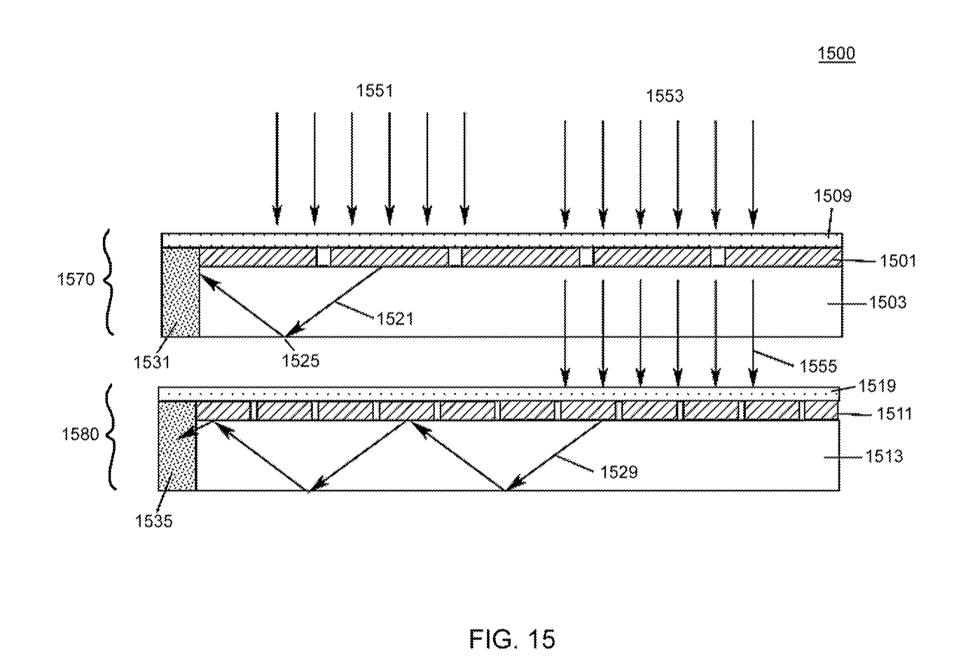

A plurality of waveguide concentrators can be arranged in tandem to absorb a relatively wide wavelength band of incident light. FIG. 15 shows a cross section diagram of one exemplary embodiment of a tandem nanoarray waveguide concentrator device 1500 including a nanoarray waveguide concentrator device 1570 disposed substantially adjacent to and optically coupled to nanoarray waveguide concentrator device 1580. Nanoarray waveguide concentrator device 1570 includes a nanoarray layer 1501 disposed adjacent to a waveguide layer 1503. A solar cell 1531 is disposed at the end surface of waveguide layer 1503. Nanoarray waveguide concentrator device 1570 is similar to the device of FIG. 12, except that it includes an optional antireflective layer 1509. Nanoarray waveguide concentrator device 1580 includes a nanoarray layer 1511 disposed adjacent to a waveguide layer 1513. A solar cell 1535 is disposed at the end surface of waveguide layer 1513. Nanoarray waveguide concentrator device 1580 is similar to Nanoarray waveguide concentrator device 1570, except that it typically has a different wavelength sensitivity.

In operation, nanoarray waveguide concentrator device 1570 receives light having two wavelength bands, the first wavelength band represented by light rays 1551 and the second wavelength band represented by light rays 1553. Photons of light rays 1551 propagate to solar cell section 1531 in the manner described hereinabove for the embodiment of FIG. 14. However, photons represented by light rays 1553 are not in a wavelength band that is scattered into trajectories that are trapped by total internal reflection in the nanoarray waveguide concentrator device 1570. A plurality of such photons (not trapped in the first nanoarray waveguide concentrator device 1570) pass through nanoarray waveguide concentrator device 1570 and emerge from the nanoarray waveguide concentrator device 1570 as photons represented by light rays 1555. Light rays 1555 are incident on the antireflective coating 1519 of nanoarray waveguide concentrator device 1580. Nanoarray waveguide concentrator device 1580 is configured to scatter the photons of light rays 1555 into light trapped trajectories, as shown by light ray 1529. Light ray 1529 propagates to solar cell 1535 by total internal reflection. Nanoarray 1511 of nanoarray waveguide concentrator device 1580 can have a different spacing and/or nano-particle diameter or other features than, for example, nanoarray layer 1501 to select the desired wavelength band. Any number of waveguide concentrators can be stacked to efficiently absorb the solar spectrum. Solar cell 1531 and solar cell 1535 can be selected so that the band gap is optimized for absorption of a particular wavelength band of light, such as in a manner known in the art of tandem solar cell design.

### Exemplary Methods and Materials of Manufacture

Dennis Slafer of the MicroContinuum Corporation of Cambridge, Mass., has described several manufacturing techniques and methods that are believed to be suitable for the manufacture of integrated solar cell nanoarray layers and light concentrator devices as described herein. For example, U.S. patent application Ser. No. 12/358,964, ROLL-TO-ROLL PATTERNING OF TRANSPARENT AND METALLIC LAYERS, filed Jan. 23, 2009, published as US 2009/0136657 A1 describes and teaches one exemplary manufacturing process to create metallic films having a plurality of nanofeatures suitable for use in surface plasmon wavelength converter devices as described herein. Also, U.S. patent application Ser. No. 12/270,650, METHODS AND SYSTEMS FOR FORMING FLEXIBLE MULTILAYER STRUCTURES, filed Nov. 13, 2008, published May 28, 2009 as US 2009-0136657 A1, U.S. patent application Ser. No. 11/814,175, REPLICATION TOOLS AND RELATED FABRICATION METHOD AND APPARATUS, filed Aug. 4, 2008, published Dec. 18, 2008 as US 2008-0311235 A1, U.S. patent application Ser. No. 12/359,559, VACUUM COATING TECHNIQUES, filed Jan. 26, 2009, published Aug. 6, 2009 as US 2009-0194505 A1, and PCT Application No. PCT/US2006/023804, SYSTEMS AND METHODS FOR ROLL-TO-ROLL PATTERNING, filed Jun. 20, 2006, published Jan. 4, 2007 as WO 2007/001977, describe and teach related manufacturing methods which are also believed to be useful for manufacturing integrated solar cell nanoarray layers and light concentrator devices as described herein. Each of the above identified United States and PCT applications is hereby incorporated herein by reference in its entirety for all purposes.

Laser interferometry is another manufacturing process that is believed to be suitable for the manufacture of integrated solar cell nanoarray layers and light concentrator devices as described herein. For example, in U.S. Pat. No. 7,304,775, Actively stabilized, single input beam, interference lithography system and method, D. Hobbs and J. Cowan described an interference lithography system that is capable of exposing high resolution patterns in photosensitive media and employing yield increasing active stabilization techniques. U.S. Pat. No. 7,304,775 is hereby incorporated herein by reference in its entirety for all purposes.

In one exemplary process, a substrate is coated with photoresist, and exposed to a laser source at defined regions that represent a complementary pattern of the desired nanopattern. Then the photoresist material is developed and the complementary nanopattern is formed in the photoresist material. This complementary nanopattern is then used as a template for the next stage in the process, which consists of deposition of the nanopatterned material (gold, silver, etc.) through a number of deposition techniques such as electron-beam evaporation and sputtering deposition. The remaining photoresist is then lifted off by chemical reagents, leaving behind the desired integrated solar cell nanoarray layers and/or light concentrator devices.

Turning now to materials useful for the manufacture of integrated solar cell nanoarray layers and light concentrator devices, integrated solar cell nanoarray layers and light concentrator devices can be made of any suitable conductor, such as for example, silver, gold, copper, aluminum, nickel, titanium, chromium, silver alloy, gold alloy, copper alloy, aluminum alloy, nickel alloy, titanium alloy, chromium alloy, or any combination thereof. Apertures (e.g., voids, holes, or nanofeatures) and/or media (e.g., dielectric media) can be present as a dielectric material, such as for example, a gas, air or silicon dioxide or a transparent conducting oxide such as tin oxide, zinc oxide, or indium tin oxide, or a semiconducting material such as silicon in any suitable form, such as for example, amorphous, crystalline, microcrystalline, nanocrystalline, or polycrystalline silicon. Copper indium gallium selenide (CIGS), and cadmium telluride (CdTe) are believed to be other suitable semiconducting materials. The apertures and/or media can be of different materials.

Other embodiments of integrated solar cell nanoarray layers and light concentrator devices (not shown in the drawings) can include combinations of any of the above structures. Where nanofeatures of integrated solar cell nanoarray layers and light concentrator devices include apertures, suitable apertures can take any form, including but not limited to, round or elliptical holes, slits, polygons, or irregular shapes. Resonant features can be of any suitable shape or morphology such as, but not limited to, ridges, bumps, depressions, and can be formed in any pattern including rings or gratings surrounding the aperture. The plurality of apertures as described in various embodiments can be periodic, non-periodic, or any combination thereof.

The shape and pattern of these intermediate light guiding nanostructures, whether they are apertures or nanoparticles, may vary and may comprise regular or irregular polygons, circles, ellipses or other geometric pattern. The thickness of the planar device has a dimension that may vary from a dimension comparable to a skin depth of a photon of solar light or to several hundreds of nanometers. The pattern of the nanostructured planar device can include a plurality of shapes such as, rods, rectangles, triangles, linear ridges, circular ridges, spiral ridges, and stars. Each one of the shapes can also have a physical dimension of about a wavelength of light, such as in a wavelength range of the terrestrial solar spectrum (300 nm to 2000 nm).

Nanoarrays as described herein can include a regular array of nanoparticles or nano-apertures in a periodic pattern. Alternatively, there can be a random or non-periodic pattern of nano structures. Nanoarrays can also include an array of nano-apertures, or alternatively a pattern of indentations that do not extend all the way through a thin film. A nanoarray can also include nanofeatures as an array of voids between two surfaces. Such physical features can also include any combination of two or more types of protrusions, depressions, apertures, or voids. For example, a pattern can be formed from a shape having an aperture surrounded by one or more protrusions. Or, a pattern can be formed from a shape having a void surrounded by a plurality of depressions.

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. An integrated energy conversion device comprising:
a nanoarray layer having a plurality of nanofeatures disposed in a pattern and configured to modify a selected one of a direction and a wavelength of photons of light incident on a surface of said nanoarray layer, said nanoarray layer having a surface;
a first material disposed adjacent to and optically coupled to one region of said surface of said nanoarray layer;
a second material disposed adjacent to and optically coupled to a second region of said surface of said nanoarray layer; and
wherein at least a selected one of said first material and said second material comprises a photovoltaic layer configured to provide an integrated solar cell electrical output voltage and an integrated solar cell electrical output current between an integrated solar cell positive output terminal and an integrated solar cell negative output terminal.

2. The integrated energy conversion device of claim 1, wherein said nanoarray layer is configured as an antireflective layer.

3. The integrated energy conversion device of claim 2, wherein a selected one of said first material and said second material comprises a thin film.

4. The integrated energy conversion device of claim 2, wherein a selected one of said first material and said second material comprises glass.

5. The integrated energy conversion device of claim 1, wherein said nanoarray layer is configured such that said integrated energy conversion device converts light incident within a range of zenith angles from zero degrees to substantially ninety degrees relative to said surface of said nanoarray layer to electricity.

6. The integrated energy conversion device of claim 1, wherein said nanoarray layer is configured as a light management layer.

7. The integrated energy conversion device of claim 6, wherein said light management layer is configured to reflect a light having a first wavelength and to transmit a light having a second wavelength.

8. The integrated energy conversion device of claim 7, wherein said light management layer is configured to reflect said light having a first wavelength to a first photovoltaic layer and to transmit said light having a second wavelength to a second photovoltaic layer.

9. The integrated energy conversion device of claim 8, wherein at least one of said first photovoltaic layer and said second photovoltaic layer is selected from the group of photovoltaic layers consisting of amorphous silicon, crystalline silicon, microcrystalline silicon, nanocrystalline silicon, polycrystalline silicon, Copper indium gallium selenide (CIGS), and cadmium telluride (CdTe).

10. The integrated energy conversion device of claim 1, wherein said nanoarray layer comprises a plurality of nanofeatures having a physical feature selected from the group of physical features consisting of depressions, protrusions, apertures, and voids.

11. The integrated energy conversion device of claim 1, wherein said nanoarray layer comprises a plurality of nanofeatures comprising patches of a metal.

12. The integrated energy conversion device of claim 1, wherein said nanoarray layer comprises a patterned metal film.

13. The integrated energy conversion device of claim 1, wherein said nanoarray layer further comprises a Lambertian surface disposed on a surface of said nanoarray.

14. The integrated energy conversion device of claim 1, wherein said nanoarray layer comprises a metal selected from the group consisting of silver, gold, copper, aluminum, nickel, titanium, chromium, silver alloy, gold alloy, copper alloy, aluminum alloy, nickel alloy, titanium alloy, chromium alloy, and a combination thereof.

15. The integrated energy conversion device of claim 1, wherein said nanoarray layer comprises a transparent conductive oxide material.

16. The integrated energy conversion device of claim 15, wherein said transparent conductive oxide material is an oxide selected from the group consisting of indium-tin-oxide (ITO), zinc oxide (ZnO), aluminum doped zinc oxide (AZO), and tin oxide (SnO2).

17. The integrated energy conversion device of claim 1, wherein a selected one of said first material and said second material comprises a waveguide layer having a waveguide layer first surface and a waveguide layer end surface, said second region of nanoarray layer surface disposed adjacent to and optically coupled to said waveguide layer first surface; and a selected other one of said first material and said second material comprises a photovoltaic section disposed adjacent to and optically coupled to said waveguide layer end surface.

18. The integrated energy conversion device of claim 17, further comprising an antireflective layer disposed on said first region of said nanoarray layer surface.

19. The integrated energy conversion device of claim 18, wherein said antireflective layer comprises a selected one of an antireflective coating and a nanoarray layer.

20. The integrated energy conversion device of claim 17, further comprising a selected one of a mirror layer disposed adjacent to and optically coupled to a waveguide layer second surface and an additional nanoarray layer disposed adjacent to and optically coupled to a waveguide layer second surface.

21. The integrated energy conversion device of claim 17, further comprising at least one additional tandem nanoarray waveguide concentrator device disposed substantially adjacent to and optically coupled to said nanoarray waveguide concentrator device.

22. The integrated energy conversion device of claim 21, wherein said nanoarray waveguide concentrator device and said additional nanoarray waveguide concentrator device are configured to operate in different wavelength bands.
